(19) United States
(12) Patent Application Publication
(10) Pub. No.: US 2012/0118358 A1
(43) Pub. Date: May 17, 2012

(54) SOLAR CELL MODULE

(75) Inventor: Seeun Hong, Changwon-si (KR)

(73) Assignee: LG ELECTRONICS INC., Seoul (KR)

(21) Appl. No.: 13/294,708

(22) Filed: Nov. 11, 2011

(30) Foreign Application Priority Data
Nov. 15, 2010 (KR) 10-2010-0113368

(51) Int. Cl. H01L 31/05; H01L 31/042; H01L 31/18; H01L 31/048

(52) U.S. Cl. 136/251; 136/244; 438/98; 257/E31.126

(57) ABSTRACT

A solar cell module includes: a front substrate; a rear substrate disposed to face the front substrate; a plurality of solar cells disposed between the front substrate and the rear substrate to generate electricity; and a plurality of ribbons disposed on a plurality of peripheral cells of the plurality of solar cells to collect generated current, each ribbon having a length shorter than that of but at least half of a length of the peripheral cell on which the ribbon is disposed.

This application claims priority to and the benefit of Korean Patent Application No. 10-2010-0113368, filed in the Korean Intellectual Property Office on Nov. 15, 2010, the entire contents of which are incorporated herein by reference for all purposes as if set forth herein.

### BACKGROUND OF THE INVENTION

1. Field of the Invention

The present invention relates to a solar cell module and methods of manufacturing the same, and more particularly, to a solar cell module for minimizing the use of ribbons collecting generated current.

2. Description of the Related Art

Recently, as existing energy resources such as oil or coal are expected to be exhausted, an interest in alternative energy for replacing oil or coal is increasing. In particular, a solar cell that directly converts (or transforms) solar energy into electricity using a semiconductor element is getting attention as a next-generation cell.

A solar cell, a device for converting (or transforming) light energy into electricity by using photovoltaic effects, may be classified into a crystalline silicon solar cell, a thin film type solar cell, a dye-sensitized solar cell, an organic solar cell, and the like. The commonly utilized crystalline silicon solar cell is disadvantageous for stably deciding the price because its material unit cost is high compared with generating efficiency, its process is complicated, and there is a big demand for the same material from various areas. Thus, in order to overcome this, an interest in a thin film solar cell in which silicon is thinly deposited on a surface of low-priced glass, plastic, or the like, is on the rise.

### SUMMARY

Accordingly, the present invention is directed to a solar cell module and methods of manufacturing the same that substantially obviate one or more of the problems due to limitations and disadvantages of the related art.

An advantage of embodiments of the present invention is to minimizing the use of ribbons for collecting generated current, thereby reducing a fabrication unit cost.

Another advantage of embodiments of the present invention is avoiding using a lead wire connecting a junction box which collects the electricity and discharges it and a ribbon.

Another advantage of embodiments of the present invention is, integrating the ribbons and the junction box, thereby improving operational efficiency and reducing a fabrication unit cost.

Additional features and advantages of embodiments of the invention will be set forth in the description which follows, and in part will be apparent from the description, or may be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described, there is provided a solar cell module including: a front substrate; a rear substrate disposed to face the front substrate; a plurality of solar cells disposed between the front substrate and the rear substrate to generate electricity; and a plurality of ribbons disposed on a plurality of peripheral cells of the plurality of solar cells to collect generated current, each ribbon having a length shorter than that of but at least half of a length of the peripheral cell on which the ribbon is disposed.

Each of the plurality of solar cells may include: a photoelectric conversion layer generating the electricity from solar light; a transparent electrode layer, to which the current generated in the photoelectric conversion layer flows, deposited on the front substrate; and a rear electrode layer, to which current generated in the photoelectric conversion layer flows, disposed on the photoelectric conversion layer.

The ribbons may be disposed on the rear electrode layer of the peripheral cells.

The ribbons may be disposed on the transparent electrode of the peripheral cells.

The plurality of solar cells may include scribed lines, and the ribbons may be disposed in the direction of the scribed lines.

The solar cell module may further include a plurality of lead wires connected to the plurality of ribbons, respectively. The lead wires may be connected to the ribbons such that the lead wires are perpendicular to the ribbons. The solar cell module may further a junction box charging and discharging the electricity generated in the solar cell and connected to the lead wires.

The solar cell module may further include a plurality of junction boxes disposed on the plurality of ribbons, respectively, and charging and discharging the electricity generated in the plurality of solar cells.

The solar cell module may further include an electric wire connecting the plurality of junction boxes; and a bypass diode disposed on the electric wire to prevent a back flow of electricity.

The plurality of peripheral cells may be disposed on the edges of the plurality of solar cells.

The ribbons may be disposed on central portions of the peripheral cells, respectively.

Lengths of a first portion and a second portion where the ribbons are not formed are half of the length of the ribbons.

The solar cell module may further include an encapsulant disposed between the plurality of solar cells and the rear substrate to attach the plurality of solar cells and the rear substrate.

The ribbons may be attached to the peripheral cells by conductive paste or a conductive film.

In another aspect, a method of manufacturing a solar cell module includes: providing a front substrate; providing a rear substrate disposed to face the front substrate; providing a plurality of solar cells disposed between the front substrate and the rear substrate to generate electricity; and providing a plurality of ribbons disposed on a plurality of peripheral cells of the plurality of solar cells to collect the generated current, each ribbon having a length shorter than that of but at least half of a length of the peripheral cell on which the ribbon is disposed.

The step of providing the plurality of solar cells may include: providing a photoelectric conversion layer generating the electricity from solar light; depositing a transparent electrode layer, to which current generated in the photoelectric conversion layer flows, on the front substrate; and providing a rear electrode layer, to which current generated in the photoelectric conversion layer flows, on the photoelectric conversion layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 is a rear view of a solar cell module according to an embodiment of the present invention.

FIG. 2 is a side-sectional view taken along line A-A of the solar cell module illustrated in FIG. 1.

FIG. 3 is a rear view of a solar cell module according to another embodiment of the present invention.

### DETAILED DESCRIPTION OF THE ILLUSTRATED EMBODIMENTS

Reference will now be made in detail to the illustrated embodiments of the present invention, which are illustrated in the accompanying drawings.

The foregoing and other objects, features, aspects and advantages of the present invention will become more apparent from the following detailed description of the present invention when taken in conjunction with the accompanying drawings. The present invention may, however, be embodied in many different forms and should not be construed as being limited to the embodiments set forth herein. Rather, these embodiments are provided so that this disclosure will be thorough and complete, and will fully convey the scope of the invention to those skilled in the art. Like numbers refer to like elements throughout the specification.

It will be understood that when an element is referred to as being “on” another element, it can be directly on the other element, or intervening elements may be present.

A solar cell module and methods of manufacturing the same according to embodiments of the present invention will now be described with reference to the accompanying drawings.

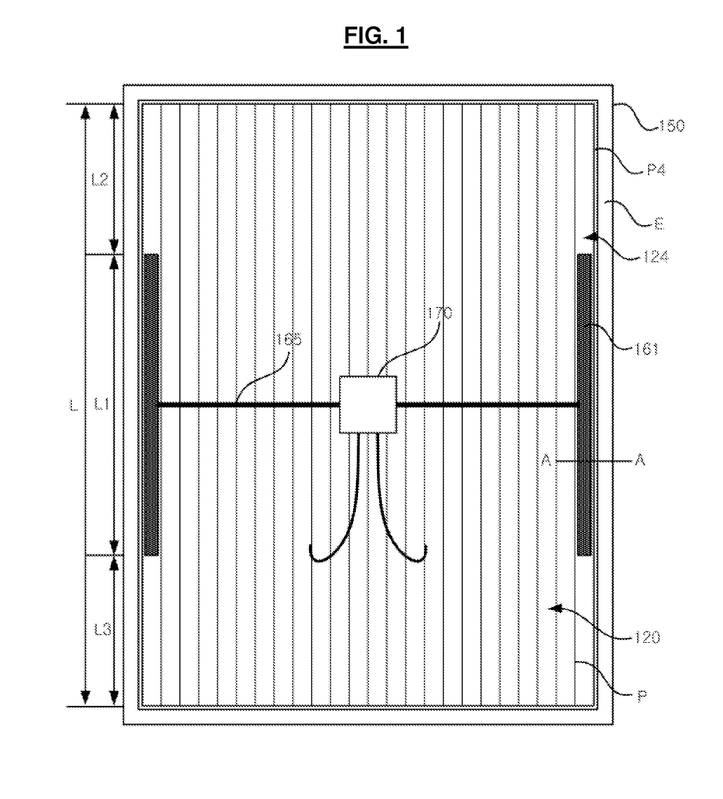

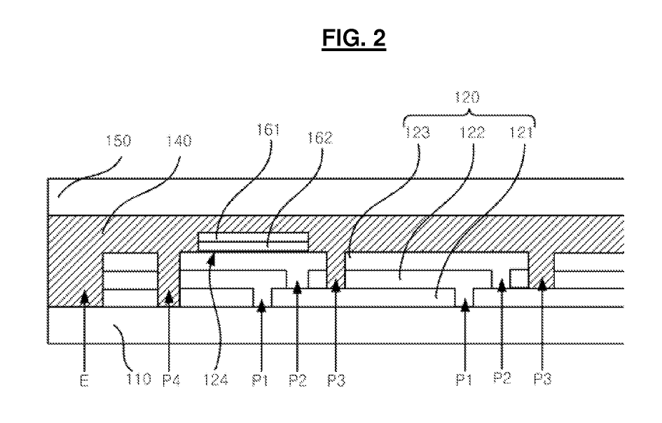

FIG. 1 is a rear view of a solar cell module according to an embodiment of the present invention, and FIG. 2 is a side-sectional view taken along line A-A of the solar cell module illustrated in FIG. 1.

A solar cell module includes a front substrate 110, which may be transparent and to which solar light may be made incident, a rear substrate 150 disposed to face the front substrate 110, a plurality of solar cells 120 disposed between the front substrate 110 and the rear substrate 150 to generate electricity, and a plurality of ribbons 161 disposed on a plurality of peripheral cells 124 of the plurality of solar cells 120 to collect the generated current, each ribbon 161 having a length shorter than that of but at least half of the peripheral cell 124 on which the ribbon is disposed.

The front substrate 110 may be made of glass allowing solar light to be transmitted therethrough, and preferably, the front substrate 110 may be made of tempered glass for protecting the solar cells 120 against an external impact, or the like. Also, in order to prevent solar light from being reflected and in order to increase transmittance of solar light, the front substrate 110 may be made of low-iron tempered glass including a small amount of iron.

The front substrate 110 may be composed of a light receiving surface to which solar light is made incident and a rear surface which is the opposite to the light receiving surface.

The plurality of solar cells 120 are disposed between the front substrate 110 and the rear substrate 150. The plurality of solar cells 120 are deposited on the front substrate 110 and generate electricity from solar light which has transmitted through the front substrate 110. With reference to FIG. 2, the plurality of solar cells 120 may include a transparent electrode layer 121 disposed on a rear surface of the front substrate 110, a photoelectric conversion layer 122 disposed on the transparent electrode layer 121 and generating electricity from solar light, and a rear electrode layer 123 disposed on the photoelectric conversion layer 122.

The transparent electrode layer 121 may be used as a passage or a channel through which current generated by the photoelectric conversion layer 122 flows. The transparent electrode layer 121 may be formed by doping any one or more materials selected from among aluminum (Al), gallium (Ga), fluorine (F), germanium (Ge), magnesium (Mg), boron (B), indium (In), tin (Sn), and lithium (Li) in zinc oxide (ZnO) or tin oxide (SnO). The transparent electrode layer 121 may be formed of AnO:Al or SnO:Al or may have a structure in which these elements are stacked.

Impurities may be able to improve electrical characteristics of zinc oxide (ZnO), and zinc oxide (ZnO) including impurities doped therein can be easily etched compared with indium tin oxide (ITO), is not toxic, and can be grown at a low temperature.

In doping impurities in the zinc oxide (ZnO), a metal element may be doped by using a doping method such as chemical doping, electrochemical doping, ion implantation, or the like, but is not limited thereto.

The surface of the transparent electrode layer 121 may have an irregular structure (or a depression and protrusion structure) in order to increase a path of light made incident thereto so that the photoelectric conversion layer 122 can absorb a larger quantity of light.

When solar light is irradiated to the photoelectric conversion layer 122 including P-N junction, electricity is generated due to a photoelectric effect. The photoelectric conversion layer 122 may be formed of amorphous silicon (a-Si), nanocrystalline silicon (uc-Si), or compound semiconductor, or may be formed as a tandem (or stack) type layer, or the like, but is not limited thereto.

The rear electrode layer 123 is deposited on the photoelectric conversion layer 122 and used as a passage allowing current generated in the photoelectric conversion layer 122 to flow therethrough along with the transparent electrode layer 121. The rear electrode layer 123 may be made of an opaque metal material such as silver (Ag) or aluminum (Al). The rear electrode layer 123 may be formed of AnO:Al or SnO:Al or may have a structure in which these elements are stacked, like the transparent electrode layer 121.

After the transparent electrode layer 123 is deposited on the rear surface of the front substrate 110, primary scribing P1 may be performed. After the photoelectric conversion layer 122 is deposited on the transparent electrode layer 123, secondary scribing P2 may be performed. After the rear electrode layer 123 is deposited on the photoelectric conversion layer 122, tertiary scribing P3 may be performed to thus discriminately form the plurality of solar cells 120, and here, the plurality of solar cells 120 are connected in series. Also, after performing the tertiary scribing P3, the plurality of solar cells 120 are insulated through quaternary scribing P4 and an edge deletion.

The plurality of solar cells 120 are discriminated by lines P formed in one direction through such scribing P1, P2, and P3. Preferably, the lines P through the scribing P1, P2, and P3 are formed in a longer side direction in the plurality of solar cells 120 substantially having a rectangular shape. The reason is because, when the transparent electrode layer 121, the photoelectric conversion layer 122, and the rear electrode layer 123 are connected, preferably, they are connected in series in a shorter side direction in the plurality of solar cells 120 having the rectangular shape.

The plurality of solar cells 120 are divided into each cell through the tertiary scribing P3, and include a plurality of peripheral cells 124 disposed at edges of the plurality of solar cells 120 between the tertiary scribing P3 and the quaternary scribing P4.

The plurality of ribbons 161 are separately disposed on the plurality of peripheral cells 124 of the plurality of solar cells 120 such that they face each other. Preferably, the plurality of ribbons 161 are disposed on the plurality of peripheral cells 124 positioned on two facing sides of the plurality of solar cells substantially having a rectangular shape. The ribbons 161 may be disposed in a direction in which the plurality of peripheral cells 124 of the plurality of solar cells 120 connected in series are connected in parallel.

The ribbons 161 are formed as a band-like thin plate and disposed in a direction parallel to the lines P formed through the tertiary scribing P3. The ribbons 161 may be formed to have a width of about a few millimeters.

The ribbon 161 may be disposed on the rear electrode layer 123 disposed on the periphery of the plurality of solar cells 120. Namely, the ribbons 161 are formed on the rear electrode layer 123 of the peripheral cell 124 of the plurality of solar cells 120. In order to effectively collect current flowing across the rear electrode layer 123, the width of each of the ribbons 161 may be half of or larger than of the width of the peripheral cells 124. Namely, the width of the ribbons 161 may be half of or larger than the width of the rear electrode layer 123 of the peripheral cells 124.

The ribbons 161 may be formed as a band-like thin plate made of a metal material having good conductivity such as copper, silver, or the like, and the ribbons 161 are made of copper foil. Each of the plurality of ribbons 161 is attached to the peripheral cells 124 of the plurality of solar cells 120 by means of conductive paste made of silver (Ag) or a conductive film formed by dispersing a plurality of conductive particles in a synthetic resin, or through spot soldering. The ribbons 161 may be directly printed on the peripheral cells 124 of the plurality of solar cells 120.

The ribbons 161 may be formed to be shorter than the length L of each of the peripheral cells 124 of the plurality of solar cells 120 but larger than half of the length (L) of each of the peripheral cells. Here, the length L of each of the peripheral cells 124 refers to a length of the longer side of the peripheral cells 124.

The length L of each of the peripheral cells 124 of the plurality of solar cells 120 and the length L of each of the ribbons 161 have a following relationship.

L/2≦L1≦L

When the length L of each of the peripheral cells 124 of the plurality of solar cells 120 is 1,362 mm, a change in output values Pmax according to a change in the length L1 of the each of the ribbons 161 is as follows.

| L1 | L1/L | Pmax (W) | Reduction rate |
|---|---|---|---|
| 1362 mm | 100% | 118.849 | 100% |
| 1200 mm | 88.10% | 118.868 | 100.02% |
| 1000 mm | 73.42% | 118.773 | 99.92% |
| 800 mm | 58.74% | 118.750 | 99.98% |
| 600 mm | 44.05% | 118.740 | 99.99% |
| 400 mm | 29.37% | 78.465 | 66.02% |
| 200 mm | 14.68% | 21.842 | 18.38% |

According to above table, it is noted that an output value is scarcely reduced even when the length L1 of the ribbon 161 is about half of the length of the peripheral cell 124 of the plurality of solar cells 120.

The length L of the peripheral cell 124 of the plurality of solar cells 120 as described above may be used to have the same meaning as the length of the line P formed through tertiary scribing P3 of the plurality of solar cells 120.

The ribbons 161 may be disposed on a central portion of each of the peripheral cells 124 in order to effectively collect current flowing across the rear electrode layer 123.

As shown in FIG. 1, the relationship among length L1 of the ribbon 161, the length L2 of a first portion where the ribbon 161 is not formed on the peripheral cell 124 of the plurality of solar cell 120, and the length L3 of a second portion where the ribbon 161 is not formed on the peripheral cell 124 may be as follows.

L2:L1:L3=1:2:1

Namely, the length L2 of the first portion and the length L3 of the second portion of the peripheral cell 124 of the plurality of solar cells 120 may be half of the length L1 of the ribbon 161.

The ribbons 161 collect current generated by the photoelectric conversion layer 122 and transfer the electricity to the exterior. The ribbons 161 collect current flowing across the transparent electrode layer 121 and the rear electrode layer 123 and transfer the collected current to the exterior. Each of the plurality of ribbons 161 is connected to a lead wire 165 to transfer the electricity to a junction box 170.

A bus bar 162 may be disposed between the ribbons 161 and the peripheral cells 124 of the plurality of solar cells 120. The plurality of bus bars 162 are disposed between the plurality of solar cells 120 and the plurality of ribbons 161. Namely, the plurality of bus bars 162 may be disposed on the rear electrode layer 123 of the plurality of peripheral cells 124.

In order to effectively collect current flowing across the rear electrode layer 123, the width of the bus bar 162 may be half of or larger than the width of the peripheral cell 124 and may be equal to the width of the ribbon 161. According to an embodiment, the width of the bus bar 162 may be larger than or slightly narrower than the width of the ribbon 161.

The bus bar 162 may be disposed on a central portion of the peripheral cells 124. Namely, the ribbons 161 may be disposed on a central portion of the bus bar 162 disposed on the central portion of the peripheral cells 124.

The bus bar 162 may be formed to have a thin band-like shape made of a metal material having good conductivity such as an alloy of aluminum (Al) and silver (Ag) or silver (Ag). The bus bar 162 may be formed to be shorter than or equal to the length L of the peripheral cell 124 of the plurality of solar cells 120, or may be formed to be longer than or equal to the length L1 of the ribbon 161. The bus bar 162 may have a length equal to that of the ribbon 161.

The junction box 170 is connected with the lead wire 165 connected to each of the plurality of ribbons 161. The junction box 170 may include a condenser provided to an outer side of the rear substrate 150 and charging and discharging the electricity and a bypass diode for preventing a back flow of electricity.

The lead wire 165 connects the plurality of ribbons 161 may be configured to include a metal material having good conductivity such as copper or silver and formed to have a thin band-like shape and an insulating film surrounding the metal material so as to be insulated from the plurality of solar cells 120. The lead wire 165 may be connected so as to be perpendicular to the ribbons 161 in the middle of the ribbons 161.

An encapsulant 140 is provided on the plurality of solar cells 120 and the front substrate 110. The encapsulant 140 is disposed between the plurality of solar cells 120 and the rear substrate 150. The encapsulant 140 cuts off external moisture or oxygen and attaches the rear substrate 150 to the plurality of solar cells 120. The encapsulant 140 may be made of ethylene-vinyl acetate copolymer (EVA), polyvinyl butyral, ethylene vinyl acetate partial oxide, a silicon resin, an ester-based resin, an olefin-based resin, or the like.

The rear substrate 150 is disposed to face the front substrate such that the plurality of solar cells 140 are disposed therebetween. The rear substrate 150 is provided on the encapsulant 140. The rear substrate 150 performs functions such as waterproofing, insulating, and filtering ultraviolet rays. The rear substrate 150 may be a TPT (Tedlar/PET/Tedlar) type rear substrate, but is not meant to be limited thereto. The rear substrate 150 may be made of a material having excellent reflexibility to reflect solar light made incident from the front substrate 110 so as to be re-used, or may be made of a transparent material allowing solar light to be made incident thereto. The rear substrate 150 may be made of the same tempered glass as that of the front substrate 110.

The operation of the foregoing solar cell module according to an embodiment of the present invention will be described as follows.

Solar cell made incident upon transmitting through the front substrate 110 transmits through the transparent electrode layer 121 and is irradiated to the photoelectric conversion layer 122. When solar light is irradiated to the photoelectric conversion layer 122, the photoelectric conversion layer 122 generates electricity. The generated current moves in the shorter side direction of the plurality of solar cells 120 along the transparent electrode layer 121 and the rear electrode layer 123 connected in series and are collected by the ribbons 161 on the rear electrode layer 123 of the peripheral cells 124. In this case, at the portions, where the ribbons 161 are not disposed, of the rear electrode layer 123 of the peripheral cells 124, the current moves to the longer side direction of the peripheral cells 124 so as to be collected by the ribbons 161. The current collected by the ribbons 161 moves to the junction box 170 along the lead wire 165 connected to the ribbons 161, and the junction box 170 charges or discharges the electricity.

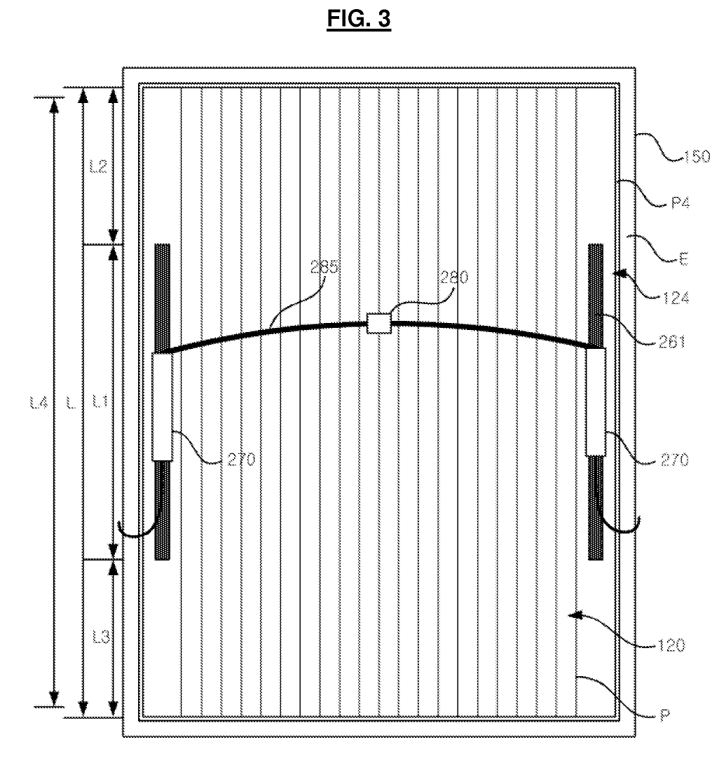

FIG. 3 is a rear view of a solar cell module according to another embodiment.

A plurality of junction boxes 270 may be disposed on a plurality of ribbons 261. The plurality of junction boxes 270 are disposed on the plurality of peripheral cells 124 of the plurality of solar cells 120.

The junction boxes 270 may have a width ranging from 10 mm to 15 mm and a length of about 100 mm so as to be disposed on the ribbons 261. The ribbons 261 may have a width of about 10 mm corresponding to the width of the junction boxes 270. Also, accordingly, the width of the peripheral cell 124 may range from 15 mm to 20 mm.

The ribbons 261, formed as a component of the junction boxes 270, may have a leaf spring form so as to increase a contact area with the rear electrode layer 123. A plurality of bus bars 162 may be disposed between the plurality of ribbons 261 and the peripheral cells 125 of the plurality of solar cells 120.

The ribbon 261 may be formed to be shorter than the length L of the peripheral cell 124 of the plurality of solar cells 120 and half of or larger than the length L of the peripheral cell 124.

The relationship between length of the peripheral cell 124 of the plurality of solar cells 120 and the length L1 of the ribbon 261 is as follows.

L/2≦L1≦L

Also, the relationship among length L1 of the ribbon 261, the length L2 of a first portion where the ribbon 261 is not formed on the peripheral cell 124 of the plurality of solar cells 120, and the length L3 of a second portion where the ribbon 261 is not formed may be as follows.

L2:L1:L3=1:2:1

The plurality of junction boxes 270 may be connected by an electric wire 285, and a bypass diode 280 for preventing a back flow of electricity may be provided to the electric wire 285. At least one of the plurality of junction boxes 270 serves as a positive (+) pole, and at least the other one may serve as a negative (−) pole.

The operation of a solar cell module according to another embodiment will now be described.

Solar cell made incident upon transmitting through the front substrate 110 transmits through the transparent electrode layer 121 and is irradiated to the photoelectric conversion layer 122. When solar light is irradiated to the photoelectric conversion layer 122, the photoelectric conversion layer 122 generates electricity. The generated current moves in the shorter side direction of the plurality of solar cells 120 along the transparent electrode layer 121 and the rear electrode layer 123 connected in series and are collected by the ribbons 261 on the rear electrode layer 123 of the peripheral cells 124. In this case, at the portions, where the ribbons 261 are not disposed, of the rear electrode layer 123, the current moves to the longer side direction of the peripheral cells 124 so as to be collected by the ribbons 261. The current collected by the ribbons 261 moves to the junction boxes 270 connected to the ribbons 261, and the junction boxes 270 charges or discharges the electricity.

It will be apparent to those skilled in the art that various modifications and variations can be made in the fabrication and application of the present invention without departing from the spirit or scope of the invention. Thus, it is intended that the present invention cover the modifications and variations of this invention provided they come within the scope of the appended claims and their equivalents.

What is claimed is:

1. A solar cell module comprising:
a front substrate;
a rear substrate disposed to face the front substrate;
a plurality of solar cells disposed between the front substrate and the rear substrate to generate electricity; and
a plurality of ribbons disposed on a plurality of peripheral cells of the plurality of solar cells to collect generated current, each ribbon having a length shorter than that of but at least half of a length of the peripheral cell on which the ribbon is disposed.

2. The solar cell module of claim 1, wherein each of the plurality of solar cells comprises:
a photoelectric conversion layer generating the electricity from solar light;
a transparent electrode layer, to which the current generated in the photoelectric conversion layer flows, deposited on the front substrate; and
a rear electrode layer, to which current generated in the photoelectric conversion layer flows, disposed on the photoelectric conversion layer.

3. The solar cell module of claim 2, wherein the ribbons are disposed on the rear electrode layer of the peripheral cells.

4. The solar cell module of claim 2, wherein the ribbons are disposed on the transparent electrode of the peripheral cells.

5. The solar cell module of claim 1, wherein the plurality of solar cells include scribed lines, and the ribbons are disposed in the direction of the scribed lines.

6. The solar cell module of claim 1, further comprising:
a plurality of lead wires connected to the plurality of ribbons, respectively.

7. The solar cell module of claim 6, wherein the lead wires are connected to the ribbons such that the lead wires are perpendicular to the ribbons.

8. The solar cell module of claim 6, further comprising:
a junction box charging and discharging the electricity generated in the solar cell and connected to the lead wires.

9. The solar cell module of claim 1, further comprising:
a plurality of junction boxes disposed on the plurality of ribbons, respectively, and charging and discharging the electricity generated in the plurality of solar cells.

10. The solar cell module of claim 9, further comprising:
an electric wire connecting the plurality of junction boxes; and
a bypass diode disposed on the electric wire to prevent a back flow of electricity.

11. The solar cell module of claim 1, wherein the plurality of peripheral cells are disposed on the edges of the plurality of solar cells.

12. The solar cell module of claim 1, wherein the ribbons are disposed on central portions of the peripheral cells, respectively.

13. The solar cell module of claim 1, wherein lengths of a first portion and a second portion where the ribbons are not formed are half of the length of the ribbons.

14. The solar cell module of claim 1, further comprising:
an encapsulant disposed between the plurality of solar cells and the rear substrate to attach the plurality of solar cells and the rear substrate.

15. The solar cell module of claim 1, wherein the ribbons are attached to the peripheral cells by conductive paste or a conductive film.

16. The solar cell module of claim 1, further comprising:
a plurality of bus bars disposed between the plurality of ribbons and the plurality of peripheral cells, respectively.

17. A method of manufacturing a solar cell module comprising:
providing a front substrate;
providing a rear substrate disposed to face the front substrate;
providing a plurality of solar cells disposed between the front substrate and the rear substrate to generate electricity; and
providing a plurality of ribbons disposed on a plurality of peripheral cells of the plurality of solar cells to collect generated current, each ribbon having a length shorter than that of but at least half of a length of the peripheral cell on which the ribbon is disposed.

18. The method of claim 17, wherein providing the plurality of solar cells comprises:
providing a photoelectric conversion layer generating the electricity from solar light;
depositing a transparent electrode layer, to which current generated in the photoelectric conversion layer flows, on the front substrate; and
providing a rear electrode layer, to which current generated in the photoelectric conversion layer flows, on the photoelectric conversion layer.
